(19) United States
(12) Patent Application Publication
(10) Pub. No.: US 2016/0025779 A1
(43) Pub. Date: Jan. 28, 2016

(54) METHOD AND CIRCUIT FOR CONFIRMING CORRECTNESS OF SIGNAL AND CHARGING SYSTEM USING SAME

(71) Applicants: Yi-Shan Chu, Zhubei City (TW); Chih-Ping Yin, New Taipei (TW); Shih-Jen Yang, New Taipei (TW)

(72) Inventors: Yi-Shan Chu, Zhubei City (TW); Chih-Ping Yin, New Taipei (TW); Shih-Jen Yang, New Taipei (TW)

(73) Assignee: RICHTEK TECHNOLOGY CORPORATION, Zhubei City (TW)

(21) Appl. No.: 14/793,512

(22) Filed: Jul. 7, 2015

Related U.S. Application Data
(60) Provisional application No. 62/027,383, filed on Jul. 22, 2014.

(51) Int. Cl. G01R 19/00; H02J 7/00

(52) U.S. Cl. CPC G01R 19/0038; H02J 7/007

(57) ABSTRACT

A method for confirming correctness of a signal includes: providing a current to flow through a time-dependent impedance circuit, wherein the time-dependent impedance circuit provides at least two resistances at two different time points, the current flowing through the time-dependent impedance circuit to generate a first voltage at a first time point, and the current flowing through the time-dependent impedance circuit to generate a second voltage at a second time point, the first voltage and the second voltage being different from each other. When a predetermined relationship exists between the first voltage and the second voltage, it is confirmed that a signal provided from a node coupled to the time-dependent impedance circuit is correct.

### CROSS REFERENCE

The present invention claims priority to U.S. 62/027,383, filed on Jul. 22, 2014.

### BACKGROUND OF THE INVENTION

1. Field of Invention

The present invention relates to a method and a circuit for confirming correctness of signal and a charging system using same; particularly, it relates to such method and circuit and charging system capable of confirming correctness of signal by checking whether a voltage variation is correct.

2. Description of Related Art

Please refer to FIG. 1, which shows a block diagram of a conventional charging system. As shown in FIG. 1, the conventional charging system 100 comprises a power adapter 10, a cable 70 and an electronic device 20. The power adapter 10 and the electronic device 20 are coupled to each other through the cable 70. The power adapter 10 comprises a power regulator 11 and a control circuit 12. The control circuit 12 controls an operation of the power regulator 11. The electronic device 20 includes a load 21. The cable 70 includes a positive power transmission line 71, a negative power transmission line 73 and a signal transmission line 72. When the power adapter 10 (acting as a power supplier) and the electronic device 20 (acting as a power receiver) are coupled to each other through the cable 70, the positive power transmission line 71 and the negative power transmission line 73 forma loop to transmit power. The signal transmission line 72 can transmit data (i.e., a communication signal CC) between a terminal CC1 of the power adapter 10 and a terminal CC2 of the electronic device 20. As shown in FIG. 1, the power adapter 10 further includes a resistor R11 coupled between a voltage VA and the signal transmission line 72 (or, the resistor R11 can be coupled between the control circuit 12 and the signal transmission line 72); the electronic device 20 further includes a resistor R12 coupled between the signal transmission line 72 and a grounding terminal GNDB. The resistor R11 and the resistor R12 form a voltage divider circuit. Thus, by setting the resistance of the resistor R12, the electronic device 20 can determine the signal provided from the terminal CC2 (the signal may indicate, for example but not limited to, a voltage level required by the load 21). The control circuit 12 can generate a control signal Vp according to the signal, so as to control the power regulator 11 correspondingly.

Under a normal circumstance, the voltage at the terminal CC2 is equal to VA*R12/(R11+R12). However, under an abnormal circumstance wherein there are dusts, threads or other unwanted material within or on the connection port between the electronic device 20 and the cable 70, the unwanted material can form a current path between the signal transmission line 72 and the negative power transmission line 73, as shown by a dashed line resistor R13. As a consequence, the voltage at the terminal CC2 will be incorrect, whereby the signal provided from the electronic device 20 through the terminal CC2 is incorrect. The drawback in this prior art is in that: the charging system 100 cannot be sure as to whether the signal provided from the electronic device 20 (power receiver) through the terminal CC2 is correct.

In view of the above, to overcome the drawback in the prior art, the present invention proposes a method and a circuit for confirming correctness of signal, and a charging system using same.

### SUMMARY OF THE INVENTION

From one perspective, the present invention provides a method for confirming correctness of a signal, comprising the steps of: providing a current to flow through a time-dependent impedance circuit, wherein the time-dependent impedance circuit provides at least two resistances at two different time points, the current flowing through the time-dependent impedance circuit to generate a first voltage at a first time point, and the current flowing through the time-dependent impedance circuit to generate a second voltage at a second time point different from the first time point, the first voltage and the second voltage being different from each other; determining whether a predetermined relationship between the first voltage and the second voltage exists; and if the predetermined relationship exists, confirming that a signal provided from a node coupled to the time-dependent impedance circuit is correct.

In one embodiment, the time-dependent impedance circuit includes: a first resistor and a second resistor connected in series with each other; and a capacitor connected in parallel with the second resistor; wherein, at the first time point, the capacitor is not charged and the first voltage is determined by a product of the current multiplied by a resistance of the first resistor; and at the second time point, the capacitor is charged and the second voltage is determined by a product of the current multiplied by a resistance of the series connection of the first resistor and the second resistor.

In one embodiment, the method for confirming correctness of the signal further comprises: discharging the capacitor before the step of generating the first voltage.

In one embodiment, the current is provided by a transmitting side whereas the time-dependent impedance circuit is located at a receiving side, and the signal provided from the node is transmitted from the receiving side to the transmitting side.

In one embodiment, the method for confirming correctness of the signal further comprises: transmitting an output from the transmitting side to the receiving side according to the signal provided from the node.

In one embodiment, the transmitting side is a power supplier and the receiving side is a power receiver.

From another perspective, the present invention provides a circuit for confirming correctness of a signal, comprising: a current source for providing a current; a time-dependent impedance circuit which provides at least two resistances at two different time points, wherein the current flows through the time-dependent impedance circuit at a first time point to generate a first voltage, and the current flows through the time-dependent impedance circuit at a second time point which is different from the first time point to generate a second voltage, the first voltage and the second voltage being different from each other; and a node coupled to the time-dependent impedance circuit, for providing a signal; wherein when a predetermined relationship exists between the first voltage and the second voltage, the signal provided from the node is correct.

From yet another perspective, the present invention provides a charging system comprising a power supplier and a power receiver, wherein the power supplier and the power receiver are connected through a cable, so that power is transmitted from the power supplier to the power receiver and a signal is transmitted from the power receiver to the power supplier via the cable, wherein the charging system comprises a circuit for confirming correctness of the signal; the circuit for confirming correctness of the signal comprising: a current source for providing a current; a time-dependent impedance circuit which provides at least two resistances at two different time points, wherein the current flows through the time-dependent impedance circuit at a first time point to generate a first voltage, and the current flows through the time-dependent impedance circuit at a second time point which is different from the first time point to generate a second voltage, the first voltage and the second voltage being different from each other; wherein the signal is provided from a node coupled to the time-dependent impedance circuit, and when a predetermined relationship exists between the first voltage and the second voltage, the signal provided from the node is correct.

In one embodiment, the time-dependent impedance circuit includes: a first resistor and a second resistor connected in series with each other; and a capacitor connected in parallel with the second resistor; wherein, at the first time point, the capacitor is not charged and the first voltage is determined by a product of the current multiplied by a resistance of the first resistor; and at the second time point, the capacitor is charged and the second voltage is determined by a product of the current multiplied by a resistance of the series connection of the first resistor and the second resistor.

In one embodiment, the circuit for confirming correctness of the signal further comprises: a switch coupled between the capacitor and the ground, for discharging the capacitor before the generation of the first voltage.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a block diagram of a conventional charging system.

FIGS. 2A-2B show a block diagram of a charging system according to an embodiment of the present invention.

FIG. 3A shows an embodiment of a charging system under a normal connection.

FIG. 3B shows an embodiment of a charging system under an abnormal connection.

FIG. 4 shows an embodiment of a control circuit.

FIG. 5 shows relationships between the first voltage and the second voltage when the charging system is under a normal connection and an abnormal connection, respectively.

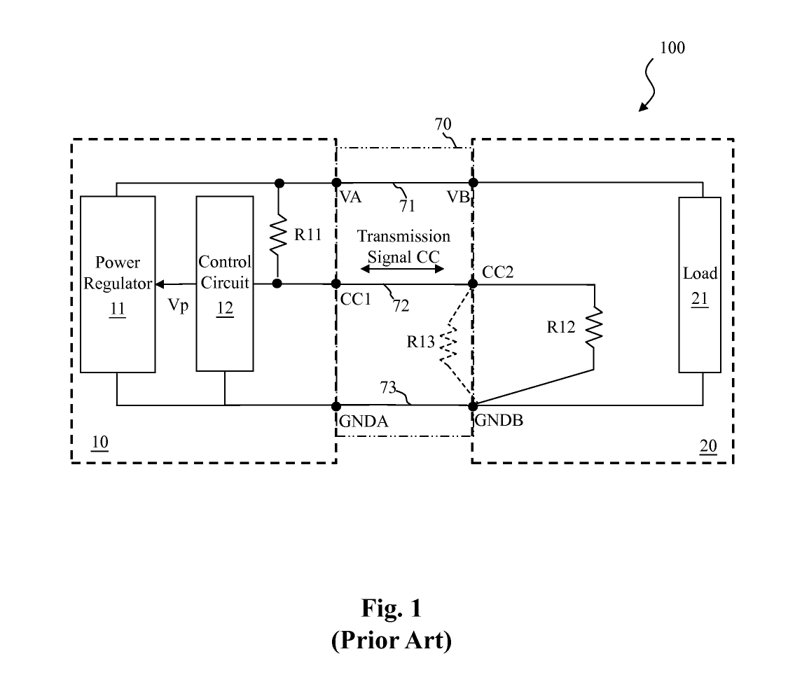

### DESCRIPTION OF THE PREFERRED EMBODIMENTS

The above and other technical details, features and effects of the present invention will be will be better understood with regard to the detailed description of the embodiments below, with reference to the drawings. The drawings as referred to throughout the description of the present invention are for illustration only, to show the interrelations between the apparatus and devices, but not drawn according to actual scale.

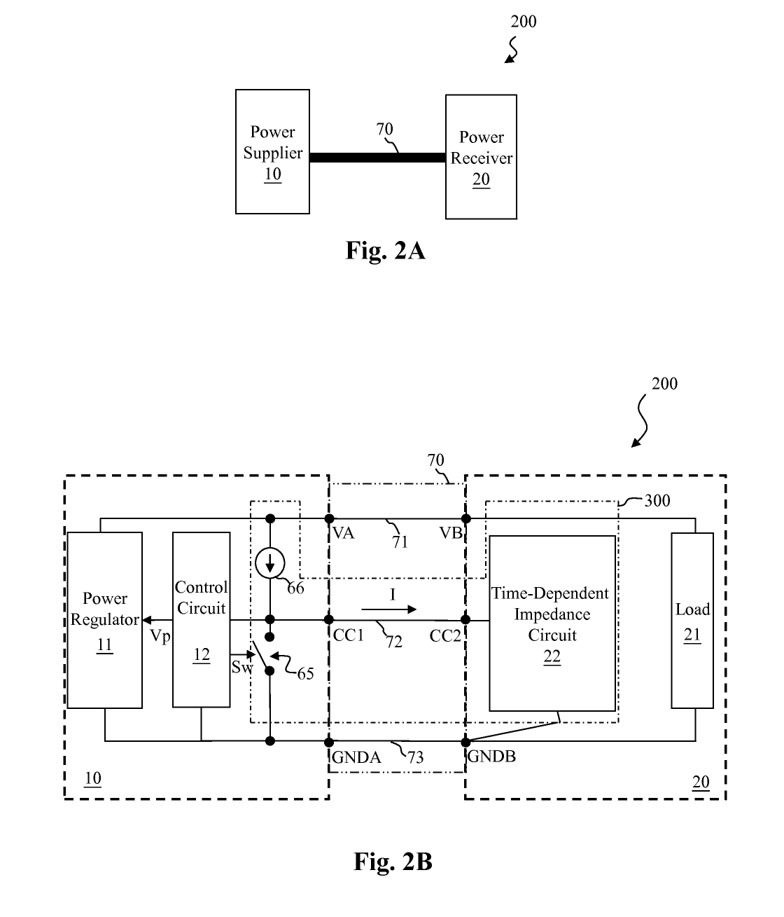

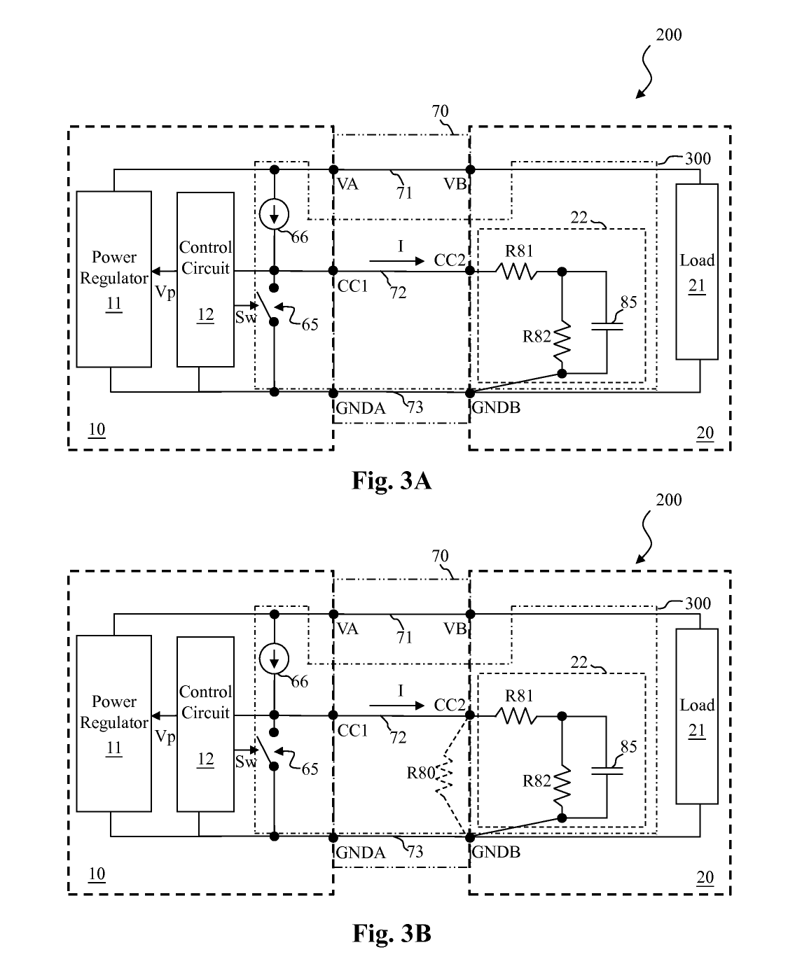

FIGS. 2A-2B show a block diagram of a charging system according to an embodiment of the present invention. FIG. 3A show an embodiment of a charging system under a normal connection. As shown in FIG. 2A, the charging system 200 of this embodiment comprises a power supplier 10, a cable 70 and a power receiver 20. The power supplier 10 and the power receiver 20 are coupled to each other through the cable 70, so that power is transmitted from the power supplier 10 to the power receiver 20. A signal can be transmitted from the power receiver 20 to the power supplier 10 via a signal transmission line 72 of the cable 70. As shown in FIG. 2B, in one embodiment, the power supplier 10 for example can be, but is not limited to a power adapter 10 (the power supplier 10 will be illustrated as the power adapter 10 hereafter). The power receiver 20 can be for example but not limited to an electronic device 20 (the power receiver 20 will be illustrated as the electronic device 20 hereafter).

As shown in FIG. 2B, the charging system 200 of this embodiment comprises a circuit 300 for confirming the correctness of the transmission signal (signal correctness confirmation circuit 300). The signal correctness confirmation circuit 300 provides a function to confirm whether the signal transmitted from the power receiver 20 to the power supplier 10 through the signal transmission line 72 is correct. More specifically, the signal correctness confirmation circuit 300 includes a current source 66, a time-dependent impedance circuit 22 and a node coupled to the time-dependent impedance circuit 22. In addition, the signal correctness confirmation circuit 300 may, optionally but not necessarily, include a switch 65. Note that the signal correctness confirmation circuit 300 is not limited to being applied in a charging system; it alone can be applied in any other application.

In the embodiment where the signal correctness confirmation circuit 300 is applied in the charging system 200, the current source 66 and the switch 65 can be located at the power supplier 10, while the time-dependent impedance circuit 22 can be located at the power receiver 20. That is, in this embodiment, the power adapter 10 includes a power regulator 11, a control circuit 12, the current source 66 and the switch 65. The current source 66 and the switch 65 in the power supplier 10 are a part of the signal correctness confirmation circuit 300. The control circuit 12 controls an operation of the power regulator 11. The power regulator 11 for example can be any type of switching power regulator, and the present invention is not limited to anyone of them. Besides, in this embodiment, the electronic device 20 includes a load 21, the time-dependent impedance circuit 22 and a node CC2. The time-dependent impedance circuit 22 and the node CC2 in the electronic device 20 are a part of the signal correctness confirmation circuit 300. The signal whose correctness is required to be confirmed is the signal provided from the node CC2 (because the node CC1 is coupled to the node CC2, the signal whose correctness is required to be confirmed can also be regarded as the signal provided from the node CC1).

The present invention confirms the correctness of the signal by providing a current I to flow through the time-dependent impedance circuit 22. The resistance of the time-dependent impedance circuit 22 is variable, and it varies along with time to provide at least two different resistances. At a first time point, the current I flows through the time-dependent impedance circuit 22 to generate a first voltage. At a second time point which is different from the first time point, the current flows through the time-dependent impedance circuit 22 to generate a second voltage. The first voltage and the second voltage are different from each other. The correctness of the signal can be confirmed by determining whether a relationship between the first voltage and the second voltage is correct.

In this embodiment, the current I is transmitted from the current source 66 at the power supplier to the time-dependent impedance circuit 22 at the power receiver. Therefore, the power supplier can be viewed as a current transmitting side, while the power receiver can be viewed as a current receiving side. Note that if the signal correctness confirmation circuit 300 is applied in other applications, the transmitting side is not necessarily a power supplier and the receiving side is not necessarily a power receiver. And, although the current source 66 is illustrated as being coupled between the voltage VA and the node CC1, it does not matter where the upper end (higher voltage end) of the current source 66 is coupled with, as long as the current source 66 can provide a known current I to the time-dependent impedance circuit 22.

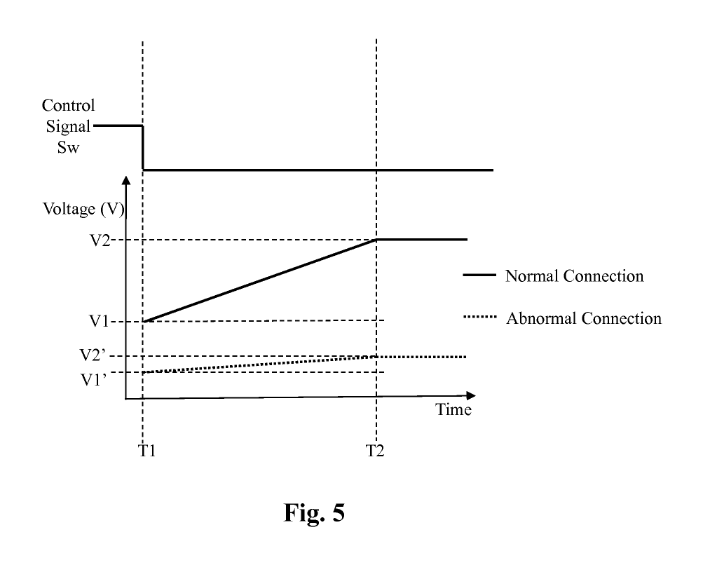

A more specific embodiment of the time-dependent impedance circuit 22 will be described below. Please refer to FIG. 2B and FIG. 3A in conjugation with FIG. 5. FIG. 5 shows relationships between the first voltage and the second voltage when the charging system is under a normal connection and an abnormal connection, respectively. As shown in FIG. 3A, in this more specific embodiment, the time-dependent impedance circuit 22 includes: a resistor R81 and a resistor R82 connected in series with each other; and a capacitor 85 connected in parallel with the resistor R82. Note that the implementation of the time-dependent impedance circuit 22 is not limited to this embodiment as shown. Any circuit implementation having the following feature can be adopted: a circuit which can provide at least two different resistances at two different time points, such that when the current I flows through the time-dependent impedance circuit 22 at a first time point, a first voltage is generated, and when the current flows through the time-dependent impedance circuit 22 at a second time point which is different from the first time point, a second voltage is generated, wherein the first voltage and the second voltage are different from each other, and a relationship between the first voltage and the second voltage can be differentiated between correct and incorrect.

In this specific embodiment, the current source 66 provides a current I. when the current I flows through the time-dependent impedance circuit 22, the resistance of the time-dependent impedance circuit 22 will vary along with time, so that different voltages are generated at the same node CC2. For example, as shown by the bold solid line in the voltage-time relationship diagram of FIG. 5, under a normal connection circumstance wherein there is no abnormal conduction path between the node C22 and the grounding terminal GNDB, a voltage V1 and a voltage V2 will be generated at different time points T1 and T2, respectively. More specifically, at the first time point T1, the capacitor 85 has not yet been charged, so when the current I flows through the time-dependent impedance circuit 22, the first voltage V1 is determined by a product of the current I multiplied by a resistance of the resistor R81. In other words, the first voltage V1 can be represented as: V1=I×R81. In addition, at the second time point T2, the capacitor 85 has been charged, so when the current I flows through the time-dependent impedance circuit 22, the second voltage V2 is determined by a product of the current I multiplied by a resistance of the series connection of the resistor R81 and the resistor R82. In other words, the second voltage V2 can be represented as: V2=I×(R81+R82). Therefore, in this embodiment, under the normal connection circumstance, a predetermined relationship will exist between the first voltage V1 and the second voltage V2. The predetermined relationship can be represented as:

$$\frac{V 1}{V 2} = \frac{I \times R 81}{I \times ( R 81 + R 82 )} = \frac{R 81}{R 81 + R 82} ( relationship 1 ) .$$

In one embodiment, the resistance of the resistor R82 can be set as, for example but not limited to, equal to the resistance of the resistor R81. Thus, the predetermined relationship between the first voltage V1 and the second voltage V2 becomes: V1/V2=1/2. Note that the resistance of the resistor R82 being equal to the resistance of the resistor R81 as described above is only one example for illustrative purpose, but not for limiting the scope of the present invention. In other embodiments, the resistance of the resistor R82 can be set as any know ratio or multiple of the resistance of the resistor R81. Once it is verified that the predetermined relationship between the first voltage V1 and the second voltage V2 is: V1/V2=R81/(R81+R82), the signal provided from the node CC2 is confirmed to be correct. Under such situation, the signal transmitted from the power receiver to the power supplier can be expressed by, for example but not limited to, a voltage level of the voltage V2.

Normally, when the circuit is starting up, the voltage across the capacitor 85 should be zero. However, to avoid any residual charges remaining in the capacitor 85 to lead to an incorrect level of the first voltage V1, in one embodiment, a switch 65 can be included. The purpose of the switch 65 is to ensure that the voltage across the capacitor 85 is zero when the first voltage V1 is generated. That is, before the current I is provided or before the first voltage V1 is generated, the switch 65 can be turned ON to discharge the capacitor 85, and then turned OFF to retrieve the level of the first voltage V1. The switch 65 can be, for example but not limited to, controlled by a signal Sw generated from the control circuit 12.

In the embodiment where signal correctness confirmation circuit 300 is applied in the charging system 200, under a normal connection circumstance (i.e., the relationship between the first voltage V1 and the second voltage V2 meets the above-mentioned predetermined relationship), the control circuit 12 can generate the control signal Vp according to the correct signal transmitted from the node CC2 of the electronic device 20 (the power receiver). The correct signal for example expresses a voltage level required by the load 21, and in response, the power regulator 11 is controlled to generate an appropriate voltage level correspondingly, provided to the load 21 via the positive power line 71. If the signal correctness confirmation circuit 300 is applied in other applications, the correct signal can be processed in any other means by any desired way, or any pre-defined response can be generated according to the correct signal.

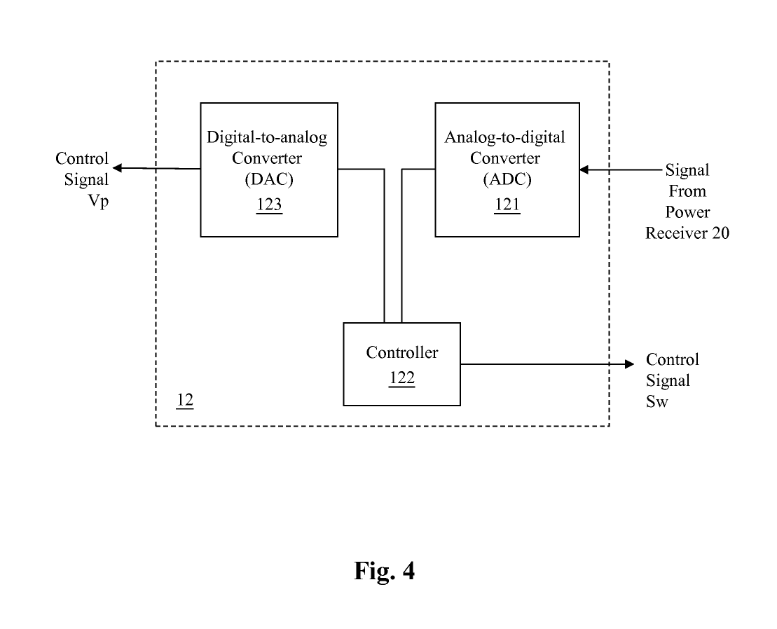

As a non-limiting example to illustrate how the control circuit 12 generates the control signal Vp according to the correct signal transmitted from the node CC2, please refer to FIG. 4, which shows an embodiment of a control circuit. The control circuit 12 includes an analog-to-digital converter (ADC) 121, a controller 122 and a digital-to-analog converter (DAC) 123. The ADC 121 receives the signal transmitted from the node CC2 of the electronic device 20 (the power receiver) and converts the signal into a digital signal. The converted digital signal is then inputted to the controller 122. The output generated form the controller 122 is converted by the DAC 123. The converted analog signal is then outputted as the control signal Vp, for controlling the power regulator 11 to generate an appropriate voltage level correspondingly. The controller 122 can further generate, in addition generating an output to the DAC 123, another control signal Sw for controlling the switch 65.

Please refer to FIG. 2B and FIG. 3B in conjugation with FIG. 5. FIG. 3B shows an embodiment of a charging system under an abnormal connection. Under an abnormal circumstance where there are dusts or other unwanted material within or on the connection port between the electronic device 20 and the cable 70, an unwanted current path may be formed between the signal transmission line 72 and the negative power transmission line 73, as shown by a dashed line resistor R80.

Under such circumstance, at the first time point T1, the capacitor 85 has not yet been charged, so when the current I flows through the time-dependent impedance circuit 22, a first voltage V1′ is generated. This first voltage V1′ is determined by a product of the current I multiplied by a resistance of the parallel connection of the resistor R81 and the resistor R80. In other words, the first voltage V1′ can be represented as:

$$V {1}^{′} = I \times \{ 1 / ( \frac{1}{R 80} + \frac{1}{R 81} ) \} .$$

Besides, at the second time point T2, the capacitor 85 has been charged, so when the current I flows through the time-dependent impedance circuit 22, a second voltage V2′ is generated. This second voltage V2′ is determined by a product of the current I multiplied by a resistance of the parallel connection of the resistor R80 and “a series connection of the resistor R81 and the resistor R82”. In other words, the second voltage V2′ can be represented as:

$$V {2}^{′} = I \times \{ 1 / [ \frac{1}{R 80} + \frac{1}{( R 81 + R 82 )} ] \}$$

As a consequence, in this embodiment, under the abnormal connection circumstance, the relationship between the first voltage V1′ and the second voltage V2′ becomes: (as shown by the dotted line in FIG. 5):

$$\frac{V {1}^{′}}{V {2}^{′}} ( relationship 2 ) .$$

Because the relationship between the first voltage V1′ and the second voltage V2′ is not equal to the above-mentioned predetermined relationship between the first voltage V1 and the second voltage V2, which is: V1/V2=R81/(R81+R82) (i.e., the relationship 2 is not equal to the relationship 1), the signal provided from the node CC2 can be confirmed to be incorrect. Under such circumstance, the control circuit 12 will not control the power regulator 11 to keep generating an inappropriate voltage level. The control circuit 12 can generate a proper response to the incorrect signal, such as but not limited to generating an alarm signal.

The prior art is unable to confirm whether the signal transmitted from the electronic device 20 (the power receiver) to the power adapter 10 (the power supplier) through the node CC2 is correct or not. In contrast, the present invention can determine whether a predetermined relationship exists between the first voltage V1 and the second voltage V2 by the signal correctness confirmation circuit 300. If it is determined yes that the predetermined relationship exists, the signal provided from the node CC2 is confirmed to be correct. As a result, if the signal correctness confirmation circuit 300 is applied in the charging system 200, the power adapter 10 (the power supplier) can generate and provide an appropriate output to the power receiver 20 according to the signal provided from the node CC2. If the signal correctness confirmation circuit 300 is applied in other applications, the correct signal can be processed properly by any other means in any other way.

The present invention has been described in considerable detail with reference to certain preferred embodiments thereof. It should be understood that the description is for illustrative purpose, not for limiting the scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. In view of the foregoing, the spirit of the present invention should cover all such and other modifications and variations, which should be interpreted to fall within the scope of the following claims and their equivalents.

What is claimed is:

1. A method for confirming correctness of a signal, comprising the steps of:
providing a current to flow through a time-dependent impedance circuit, wherein the time-dependent impedance circuit provides at least two resistances at two different time points, the current flowing through the time-dependent impedance circuit to generate a first voltage at a first time point, and the current flowing through the time-dependent impedance circuit to generate a second voltage at a second time point different from the first time point, the first voltage and the second voltage being different from each other;
determining whether a predetermined relationship between the first voltage and the second voltage exists; and
if the predetermined relationship exists, confirming that a signal provided from a node coupled to the time-dependent impedance circuit is correct.

2. The method for confirming correctness of the signal of claim 1, wherein the time-dependent impedance circuit includes:
a first resistor and a second resistor connected in series with each other; and
a capacitor connected in parallel with the second resistor;
wherein, at the first time point, the capacitor is not charged and the first voltage is determined by a product of the current multiplied by a resistance of the first resistor; and
at the second time point, the capacitor is charged and the second voltage is determined by a product of the current multiplied by a resistance of the series connection of the first resistor and the second resistor.

3. The method for confirming correctness of the signal of claim 2, further comprising:
discharging the capacitor before the step of generating the first voltage.

4. The method for confirming correctness of the signal of claim 1, wherein the current is provided by a transmitting side and the time-dependent impedance circuit is at a receiving side, wherein the signal provided from the node is transmitted from the receiving side to the transmitting side.

5. The method for confirming correctness of the signal of claim 4, further comprising:
transmitting an output from the transmitting side to the receiving side according to the signal provided from the node.

6. The method for confirming correctness of the signal of claim 4, wherein the transmitting side is a power supplier and the receiving side is a power receiver.

7. A circuit for confirming correctness of a signal, comprising:
a current source for providing a current;
a time-dependent impedance circuit which provides at least two resistances at two different time points, wherein the current flows through the time-dependent impedance circuit at a first time point to generate a first voltage, and the current flows through the time-dependent impedance circuit at a second time point which is different from the first time point to generate a second voltage, the first voltage and the second voltage being different from each other; and
a node coupled to the time-dependent impedance circuit, for providing a signal;
wherein when a predetermined relationship exists between the first voltage and the second voltage, the signal provided from the node is correct.

8. The circuit for confirming correctness of the signal of claim 7, wherein the time-dependent impedance circuit includes:
a first resistor and a second resistor connected in series with each other; and
a capacitor connected in parallel with the second resistor;
wherein, at the first time point, the capacitor is not charged and the first voltage is determined by a product of the current multiplied by a resistance of the first resistor; and
at the second time point, the capacitor is charged and the second voltage is determined by a product of the current multiplied by a resistance of the series connection of the first resistor and the second resistor.

9. The circuit for confirming correctness of the signal of claim 8, further comprising:
a switch coupled between the capacitor and the ground, for discharging the capacitor before the generation of the first voltage.

10. A charging system comprising a power supplier and a power receiver, wherein the power supplier and the power receiver are connected through a cable, so that power is transmitted from the power supplier to the power receiver and a signal is transmitted from the power receiver to the power supplier via the cable, wherein the charging system comprises a circuit for confirming correctness of the signal; the circuit for confirming correctness of the signal comprising:
a current source for providing a current;
a time-dependent impedance circuit which provides at least two resistances at two different time points, wherein the current flows through the time-dependent impedance circuit at a first time point to generate a first voltage, and the current flows through the time-dependent impedance circuit at a second time point which is different from the first time point to generate a second voltage, the first voltage and the second voltage being different from each other;
wherein the signal is provided from a node coupled to the time-dependent impedance circuit, and when a predetermined relationship exists between the first voltage and the second voltage, the signal provided from the node is correct.

11. The charging system of claim 10, wherein the time-dependent impedance circuit includes:
a first resistor and a second resistor connected in series with each other; and
a capacitor connected in parallel with the second resistor;
wherein, at the first time point, the capacitor is not charged and the first voltage is determined by a product of the current multiplied by a resistance of the first resistor; and
at the second time point, the capacitor is charged and the second voltage is determined by a product of the current multiplied by a resistance of the series connection of the first resistor and the second resistor.

12. The charging system of claim 10, wherein the circuit for confirming correctness of the signal further comprises:
a switch coupled between the capacitor and the ground, for discharging the capacitor before the generation of the first voltage.
